(19) United States
(12) Patent Application Publication
(10) Pub. No.: US 2012/0039034 A1
(43) Pub. Date: Feb. 16, 2012

(54) Transflective LCD With Arcuate Pixel Portions

(76) Inventors: Mary Lou Jepsen, Sausalito, CA (US); Carlin Vieri, Menlo Park, CA (US)

(21) Appl. No.: 13/208,528

(22) Filed: Aug. 12, 2011

Related U.S. Application Data
(60) Provisional application No. 61/373,758, filed on Aug. 13, 2010.

(51) Int. Cl. H05K 7/00; H01J 9/24; G02F 1/1335

(52) U.S. Cl. 361/679.21; 349/114; 445/24

(57) ABSTRACT

Techniques are provided for a transflective liquid crystal display comprising a plurality of subpixels. Each subpixel comprises a reflective part having a reflective-part cell gap and a transmissive part having a transmissive-part cell gap. A subpixel may comprise minimal perimeters of a first minimal area between the transmissive part and the reflective part. At least one of the one or more minimal perimeters defines one or more edges of a second maximal area of the transmissive part.

### BENEFIT CLAIM

This application claims the benefit, under 35 U.S.C. 119(e), of prior provisional application 61/373,758, filed Aug. 13, 2010, the entire contents of which are hereby incorporated by reference for all purposes as if fully set forth herein.

### CROSS REFERENCE TO RELATED APPLICATIONS

This application is related to U.S. patent application Ser. No. 12/712,439, filed Feb. 25, 2010; and U.S. patent application Ser. No. 12/782,574, filed May 18, 2010, the entire contents of which are hereby incorporated by reference for all purposes as if fully disclosed herein.

### TECHNICAL FIELD

The present disclosure relates to Liquid Crystal Displays (LCDs).

### BACKGROUND

The approaches described in this section are approaches that could be pursued, but not necessarily approaches that have been previously conceived or pursued. Therefore, unless otherwise indicated, it should not be assumed that any of the approaches described in this section qualify as prior art merely by virtue of their inclusion in this section.

Transflective LCDs may be used in cell phones, electronic books, and computers. Reading with transflective LCDs is possible even in strong ambient lighting. A transflective LCD comprises an array of pixels or subpixels each having a reflective part and a transmissive part. A transflective LCD may operate in different modes, for example, a reflective-only mode, a transmissive-only mode, or a transflective mode.

As a LCD pixel or subpixel comprises both a transmissive part and a reflective part, a transflective LCD is typically more expensive to manufacture than an LCD with either only transmissive pixels or only reflective pixels.

In addition, a transflective LCD may comprise a liquid crystal layer with more than one cell gap and requires relatively tight and accurate cell gap control in manufacturing processes. As a result, the yield may be reduced, while the cost from the manufacturing processes may be increased.

### BRIEF DESCRIPTION OF THE DRAWINGS

In the drawings:

FIG. 1A and FIG. 1B illustrate schematic partial cross-sectional views of an example LCD subpixel.

FIG. 2A, FIG. 2B, FIG. 2C, FIG. 2D, and FIG. 2E illustrate schematic partial plan views of an example transflective LCD subpixel.

FIG. 3 illustrates a computer with which embodiments may be used.

The drawings are not rendered to scale.

### DETAILED DESCRIPTION

Techniques for transflective LCDs with arcuate pixel portions are described. Various modifications to the preferred embodiments and the generic principles and features described herein will be readily apparent to those skilled in the art. Thus, the present invention is not intended to be limited to the embodiments shown, but is to be accorded the widest scope consistent with the principles and features described herein.

### 1. General Overview

In some embodiments, a transflective LCD subpixel comprises a liquid crystal layer that uses the electrically controlled birefringence (ECB) effect for achieving high transmittance, high reflectance, and high brightness of the transmissive part through a simplified device structure with fewer retardation films for cost saving. As used herein, a subpixel may refer to a LCD unit structure that may be used as a specific color subpixel of a pixel that comprises multiple subpixels, or alternatively and/optionally as a pixel directly.

Benefits of this approach include a transflective LCD with high backlight output efficiency. Additional benefits include a transflective LCD characterized by higher brightness and significantly lower power consumption. These characteristics are valuable for various applications in different operating modes. For example, the transflective LCD embodiments described herein can support various operating modes including but not limited to displaying color images in the transmissive mode and the transflective mode, and black-and-white monochromatic images in the reflective mode with good readability in the presence of ambient light and low power consumption.

In an embodiment, a transflective liquid crystal display comprises a plurality of subpixels. Each subpixel in the transflective liquid crystal display comprises a reflective part having a reflective-part cell gap and a transmissive part having a transmissive-part cell gap.

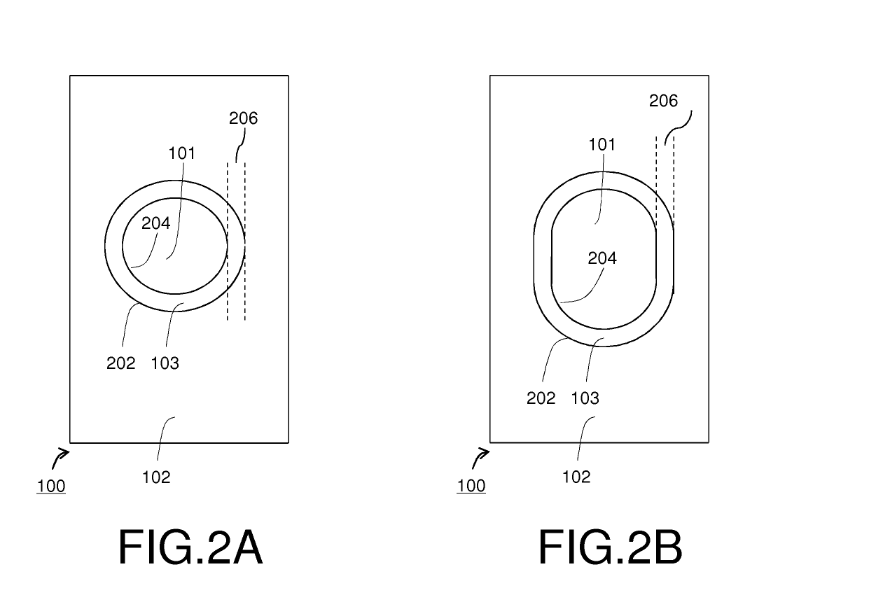

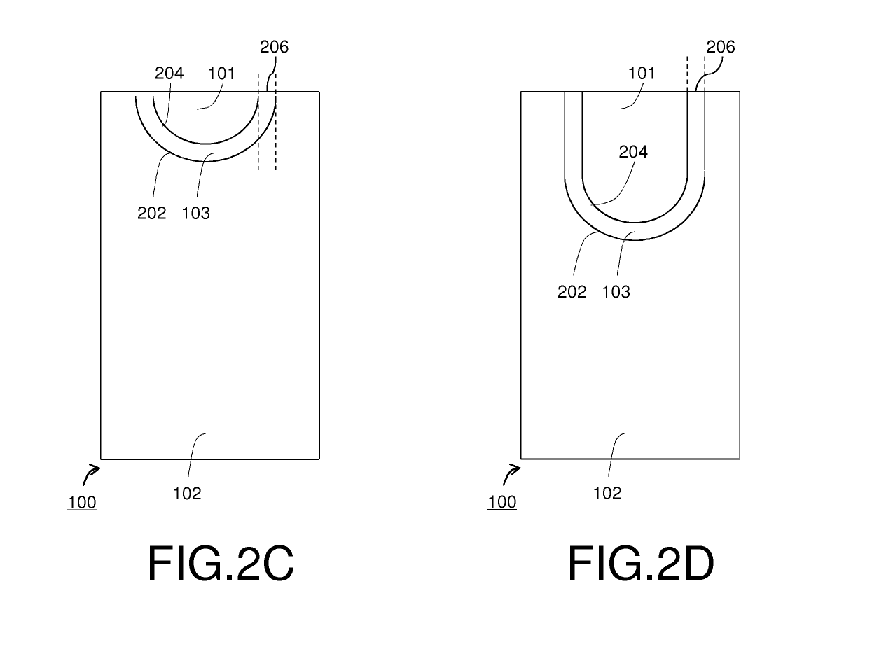

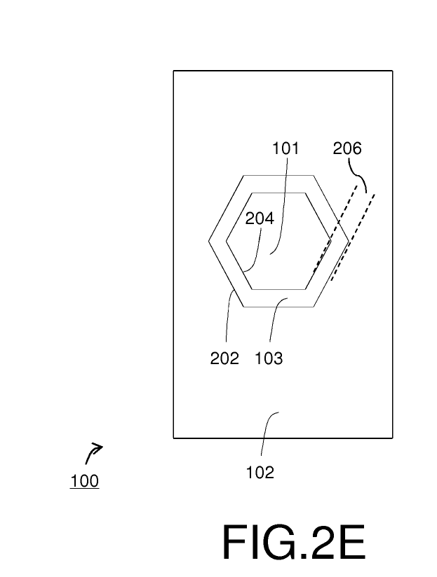

In embodiments, a subpixel as described herein comprises one or more minimal perimeters of a first minimal area between the transmissive part and the reflective part. At least one (e.g., a second perimeter 204 of FIG. 2A through FIG. 2E) of the one or more minimal perimeters defines one or more edges of a second maximal area of the transmissive part.

In an embodiment, a minimal perimeter of the first minimal area comprises at least one arcuate segment. In an embodiment, a minimal perimeter of the first minimal area forms a circle. In an embodiment, a minimal perimeter of the first minimal area forms a semicircle. In an embodiment, a minimal perimeter of the first minimal area comprises at least one line segment and at least one arcuate segment. In an embodiment, a minimal perimeter of the first minimal area comprises a plurality of interconnected line segments that approximate an arcuate segment.

In some embodiments, a transflective LCD as described herein forms a part of a computer, including but not limited to a laptop computer, netbook computer, cellular radiotelephone, electronic book reader, point of sale terminal, desktop computer, tablet computer, computer workstation, computer kiosk, or computer coupled to or integrated into a gasoline pump, and various other kinds of terminals and display units.

In some embodiments, a method comprises providing a transflective LCD as described, and a backlight source to the transflective LCD.

Various modifications to the preferred embodiments and the generic principles and features described herein will be readily apparent to those skilled in the art. Thus, the disclosure is not intended to be limited to the embodiments shown, but is to be accorded the widest scope consistent with the principles and features described herein.

### 2. Structural Overview

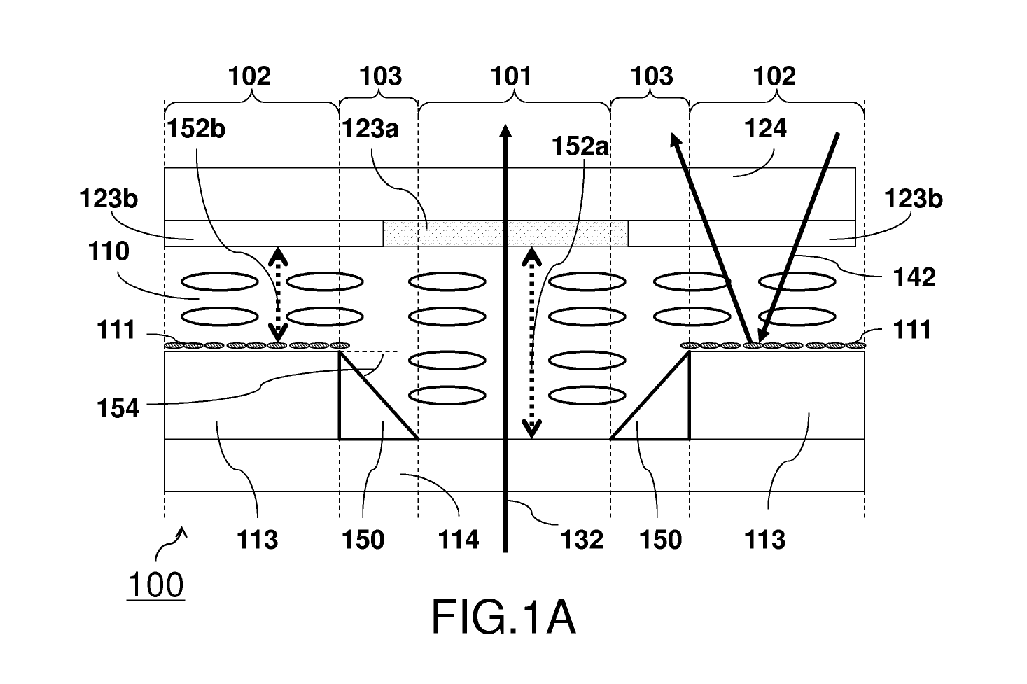

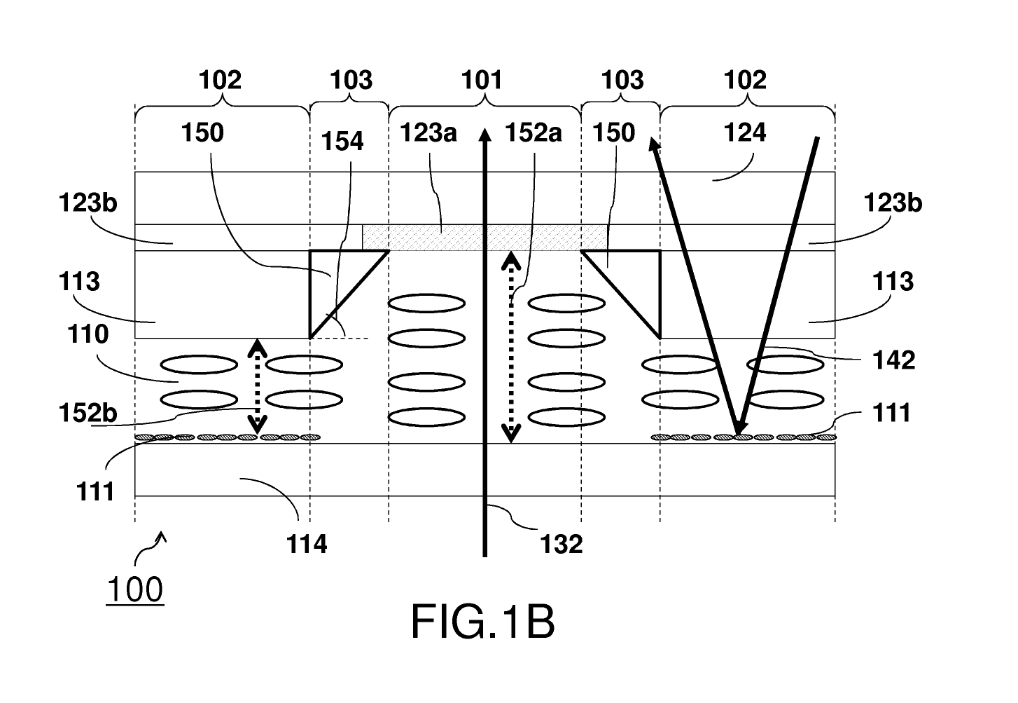

FIG. 1A and FIG. 1B illustrate schematic cross-sectional views of an example transflective LCD subpixel 100 in two different configurations. As used in this disclosure, “a transflective LCD subpixel” may refer to a pixel or a subpixel in the transflective LCD. The LCD subpixel 100 may comprise two or more parts. As illustrated, the LCD subpixel 100 comprises a transmissive part 101, a reflective part 102, and a transition region 103 between the transmissive part 101 and the reflective part 102.

The LCD subpixel 100 comprises a layer 110 of homogeneously aligned liquid crystal material. The liquid crystal layer 110 may be filled into a cell space by a capillary effect or a one-drop filling process under the vacuum condition. In some embodiments, the liquid crystal layer 110 is of a positive dielectric anisotropy type with Δε>0. In some embodiments, the liquid crystal layer 110 is of a negative dielectric anisotropy type with Δε<0. In different embodiments, liquid crystal materials with different birefringence properties may be used in the liquid crystal layer 110.

In some embodiments, rubbed polyimide layers, not shown in FIG. 1A and FIG. 1B, may be formed adjacent to the liquid crystal layer 110 to induce the liquid crystal layer 110 near a rubbed polyimide layer to be homogeneously aligned along a rubbing direction in parallel with the planar surfaces of the substrate layers 114 and 124.

The transmissive part 101 may have a different cell gap than that of the reflective part 102. As used in this disclosure, “a cell gap” or “a liquid crystal cell gap” refers to the thickness of the liquid crystal layer in either the transmissive part or the reflective part.

In some embodiments, as illustrated in FIG. 1A, the LCD subpixel 100 comprises an over-coating layer 113 on or near a bottom substrate layer 114 in the reflective part 102.

In some embodiments, as illustrated in FIG. 1B, the over-coating layer 113 is located adjacent to the top glass substrate 124.

The over-coating layer 113 may be formed in a plurality of partially etched regions by a photolithographic etching process. In some embodiments, in part due to the over-coating layer 113, the liquid crystal cell gap in the reflective part 102 may be approximately half of the liquid crystal cell gap in the transmissive part 101. In various embodiments, the over-coating layer 113 may comprise acrylic resin, polyamide, or novolac epoxy resin.

In the transition region 103, the over-coating layer 113 comprises a sloped region 150 which graduates from a first thickness configured to create a reflective-part cell gap 152b in the reflective part 102 to a second thickness configured to create a transmissive-part cell gap 152a in the transmissive part 101. In some embodiments, the reflective-part cell gap 152b is one half of the transmissive-part cell gap 152a. In some embodiments, the second thickness of the over-coating layer 113 is zero. In some embodiments, the second thickness of the over-coating layer 113 is 1%, 2%, or another smaller or larger percentage of the first thickness of the over-coating layer 113. In various embodiments, the sloped region 150 may comprise a linear slope or a curvilinear slope or an irregular slope. A slope angle 154 of the sloped region 150 may be defined as the largest angle between the edge of the sloped region 150 at the reflective part 102 and the other edge of the sloped region 150 at the transmissive part 101.

In a configuration illustrated by FIG. 1A, the inner surface, which is the top surface, of over-coating layer 113 may be covered with a metallic reflective layer 111. The metallic layer 111 may continue down the transition region and possibly end before or at the edge of the transmissive part 101. In some embodiments, the over-coating layer 113 including the sloped region 150 may be covered by metal, and the metal may extend a little bit into the transmissive part 101. Alternatively, in another configuration illustrated by FIG. 1B, the inner surface of over-coating layer 113 may be smooth and free of a metallic reflective layer; the metallic reflective layer 111 may be located in the reflective part 102 adjacent to the bottom substrate layer 114.

In some embodiments, the metallic reflective layer 111 may be a bumpy metal layer. In some embodiments, the metallic reflective layer 111 may comprise aluminum (Al), silver (Ag) or another metallic composition and/or alloy to work as a reflective electrode.

The bottom substrate layer 114 may be made of glass at or near which a transparent indium-tin oxide (ITO) layer may be provided as a first electrode (common or pixel electrode).

One, two, or more color filters 123a may be deposited on or near a surface of a top substrate 124. The color filters may cover both the transmissive part 101 and the reflective part 102, or only cover the transmissive part 101. If two or more color filters are used to cover some portions of the subpixel, the color filters may impart different colors. In some embodiments, at least one of the color filters covers the transmissive part 101. There may be red, green and blue (RGB) color filters 123a deposited on or near the inner surface, which faces the liquid crystal layer 110, of the top substrate 124 in the transmissive part 101.

In areas that are not covered by the color filters 123a, a second over-coating layer 123b may be configured. The second over-coating layer 123b may be a passivation layer comprising an organic material such as a-Si:C:O and a-Si:O:F, or an inorganic material such as silicon nitride (SiNx) and silicon oxide (SiO2), prepared by plasma enhanced chemical vapor deposition or other similar sputtering methods.

An ITO layer may be located between the top substrate 124 and the liquid crystal layer 110 as a second electrode. One or more of a bottom linear polarizer and a top linear polarizer may be attached on outer surfaces of the bottom substrate and top substrate.

A switch element in the subpixel 100 may be used to control whether a reflective-part pixel electrode in the reflective part 102 is connected or disconnected with a transmissive-part pixel electrode in the transmissive part 101. For example, in some operating modes of a transflective LCD display comprising the LCD subpixel 100, the switch element under display mode control logic may cause the reflective-part pixel electrode to be connected to the transmissive-part pixel electrode; the pixel electrodes thus may be driven by the same signal to cause the transmissive part 101 and the reflective part 102 to simultaneously express a same pixel or subpixel value in tandem. In some other operating modes, the switch element under display mode control logic may cause the reflective-part pixel electrode to be disconnected from the transmissive-part pixel electrode; the pixel electrodes in the transmissive part 101 and reflective part 102 may thus be driven by separate signals to cause the transmissive part 101 and the reflective part 102 to independently express different pixel or subpixel values. For example, in a transmissive operating mode, the transmissive part 101 may be set according to a pixel or subpixel value based on image data, while the reflective part 102 may be set in a dark black state. In a reflective operating mode, on the other hand, the reflective part 102 may be set according to a pixel or subpixel value based on image data, while the transmissive part 101 may be set in a dark black state.

In some embodiments, reflective-part liquid crystal layer portion and transmissive-part liquid crystal layer portion may be driven with the same voltage range values. However, even so, different voltage values may be concurrently and separately applied to a reflective-part liquid crystal layer portion in the reflective part 102 and to a transmissive-part liquid crystal layer portion in the transmissive part 101. In some other embodiments, reflective-part liquid crystal layer portion and transmissive-part liquid crystal layer portion may be driven with by two separate ranges of voltage values. Thus, in these other embodiments, a first voltage range values may be used to drive the reflective-part liquid crystal layer portion in the reflective part 102, while a second different voltage range values may be used to drive the transmissive-part liquid crystal layer portion in the transmissive part 101.

The switch element may be implemented by one or more thin-film transistors (TFTs) hidden beneath the metallic reflective layer 111 in the reflective part 102 to improve the aperture ratio of the transflective LCD.

In some embodiments, one or more retardation films may be provided as a part of the optical structure of the subpixel 100.

In the transmissive part 101, transmissive light 132 (which may for example emitted from a backlight unit) crosses the liquid crystal layer 110 towards a viewer (along the up direction—which is the z direction if the x and y directions of a Cartesian coordinate system lie in the viewer-facing surface of the transflective display panel—of FIG. 1A and FIG. 1B). In the reflective part 102, the light path of ambient light 142 crosses the liquid crystal layer 110 twice.

As used herein, a pixel in a transflective LCD display as described herein may comprise one, two, three or more subpixels; so a plurality of subpixels arranged in a pattern may be configured to provide a plurality of pixels in a transflective display panel.

A transmissive part as described herein may or may not be covered fully or partially by color filters. In some embodiments, no color filters are used to cover a transmissive part as described herein. In these embodiments, one or more colored light sources may provide light to transmissive parts. For example, a red light source may be used for the transmissive part of a first subpixel, a green light source may be used for the transmissive part of a second subpixel, and a blue light source may be used for the transmissive part of a third subpixel. In other embodiments, other color systems may be used and/or a different combination of colored light sources may be used.

### 3. Transition Region Minimization

In a transition region of a subpixel such as 103 of FIG. 1A and FIG. 1B, optical performance is suboptimal or penalized (e.g., with a 12%, 30%, 50% or another higher or lower penalty), relative to a reflective part and a transmissive part of the subpixel with their respective configured cell gaps, as the subpixel is generally designed to operate optimally at certain cell gaps present in the transmissive part 101 and the reflective part 102, respectively. In the transition region 103, because of the variation in the cell gap and the surface slope in the sloped region 150, optical properties such as contrast ratio, or other operating behaviors of the liquid crystal material in the transition region 103 may be degraded relative to that in the transmissive part 101 and the reflective part 102. The slope and/or gradient of the sloped region 150 in the over-coating layer 113 may also disturb alignment of the liquid crystal material in the subpixel 100, further compromising optical performance of the subpixel 100.

It is therefore desirable to provide a minimal horizontal area (as projected to the display panel surface) of the transition region 103 and a maximal horizontal area of the transmissive part 101 for targeted, intended, optimal, and/or stable optical performance. Under techniques as described herein, a manufacturing process may be selected on the basis of making the slope as steep as possible (e.g., to make the slope angle 154 as close to 90 degrees as possible), thereby minimizing the horizontal distance from the thick part to the thin part of the sloped region 150 and hence the horizontal area of the transition region 103. If the slope could be made perfectly vertical, the horizontal distance would be close to zero and the optical degradation of the transition region would be minimized; however, practical limitations or considerations (which may include, but are not limited to only, increasing manufacturing costs and complexity) in the design or in the manufacturing process exist to limit increasing the slope of the transition region. Techniques as described herein may be used to significantly overcome, and reduce/remove the suboptimal effects caused by, the practical limitations, even if the horizontal distance of the transition region cannot be made as negligible by the selected manufacturing process. Benefits of these techniques include allowing the use of relatively simple, relatively inexpensive manufacturing techniques and creating subpixels with relatively high optical performance in various operating modes.

In some embodiments, techniques as described herein may be used to minimize the horizontal area of the transition region 103 while maximizing the active horizontal areas of the pixel area (e.g., transmissive part 101 and/or reflective part 102).

The transition region 103 may comprise one or more perimeters formed or projected onto the display panel surface by the thick and thin edges of the sloped region 150 in the transition region 103. In an embodiment, the thick and thin edges of the sloped region 150 in the transition region 103 constitute edges of the transmissive part 101 and the reflective part 102, respectively. The edges of the transmissive part 101 and the reflective part 102 may be defined by two perimeters, one of which may be formed by the thick edge of the transition region 103 adjacent to the reflective part 102, and the other of which may be formed by the thin edge of the transition region 103 adjacent to the transmissive part 101.

As used herein, geometric terms such as line segments, arcuate segments, curved segments, horizontal distances, perimeters, horizontal areas, etc., are not used in the context of a line drawing of geometric shapes on paper; rather, these terms refer to line segments, arcuate segments, curved segments, horizontal distances, perimeters, horizontal areas, etc., representing three-dimensional constituent parts of a three-dimensional subpixel. In particular, these terms may refer to line segments, arcuate segments, curved segments, horizontal distances, perimeters, horizontal areas, etc., representing the shapes or edges, as projected to a viewing surface of a display panel that comprises the subpixel, of the three-dimensional constituent parts of the subpixel. As used herein, the term “arcuate segment” refers to curved segment such as arc segment, semicircle, circle, ellipse, etc., that may be used to minimize a transition region between a transmissive part and a reflective part in a subpixel.

The total horizontal area (e.g., within, or projected to, the display panel surface) of the transition region 102 is approximately equal to a perimeter (e.g., separating the transition region 103 and the transmissive part 101) multiplied by the horizontal distance (e.g., along, or projected to, the display panel surface) between the thick edge and the thin edge of the sloped region 150 as projected to the display panel surface. As used herein, the horizontal distance as mentioned above may vary along a perimeter and may specifically refer to an average horizontal distance between the two perimeters.

Under techniques as described herein, to provide a minimal horizontal area of the transition region 103, the perimeters of the transition region 103 may be minimized in the layout of the subpixel. Under techniques herein, a layout of the subpixel may be selected, based on one or more geometric, manufacturing-related, design-tool-related, or other types of factors or constraints, from a plurality of possible layouts of the subpixel. The selected layout may comprise a minimal perimeter.

FIG. 2A through FIG. 2D illustrate example top-view structures of a subpixel (e.g., 100 of FIG. 1A and FIG. 1B), according to some embodiments.

In FIG. 2A, the subpixel (e.g., 100 of FIG. 1A and FIG. 1B) comprises a transmissive part (e.g., 101 of FIG. 1A and FIG. 1B) in the form of a circle shape and a reflective part (e.g., 102 of FIG. 1A and FIG. 1B) in the form of a rectangle minus another circle shape concentric with, but larger than, that of the transmissive part 101. In FIG. 2A, the subpixel 100 also comprises a transition region (e.g., 103 of FIG. 1A and FIG. 1B) in the form of an area in between the two circle shapes as mentioned.

In FIG. 2C, the subpixel (e.g., 100 of FIG. 1A and FIG. 1B) comprises a transmissive part (e.g., 101 of FIG. 1A and FIG. 1B) in the form of a semicircle shape and a reflective part (e.g., 102 of FIG. 1A and FIG. 1B) in the form of a rectangle minus another semicircle shape concentric with, but larger than, that of the transmissive part 101. In FIG. 2C, the subpixel 100 also comprises a transition region (e.g., 103 of FIG. 1A and FIG. 1B) in the form of an area in between the two semicircle shapes as mentioned.

In FIG. 2A through FIG. 2D, the transition region 103 comprises a first perimeter (202) and a second perimeter (204), and may be optically suboptimal for reflection and transmission of light. If the horizontal distance (206) between the first perimeter 202 and the second perimeter 204 is small relative to the length of the lesser of the perimeters 202 and 204, then the entire area of the transition region 103 is approximately the horizontal distance (206) times either of the first perimeter 202 and the second perimeter 204 (in length).

In some embodiments, the horizontal distance 206 may be preset or preconfigured based on one or more design considerations. In some embodiments, the horizontal distance 206 of the transition region 103 may be estimated and/or determined (e.g., through trial run, simulation, etc.) based on capabilities and/or properties of a manufacturing process for making the subpixel 100. For example, the manufacturing process may be configured to support generating the horizontal distance 206 to graduate from the thick (outer in this example) edge of a sloped region (e.g., 150 of FIG. 1A and FIG. 1B), as defined by the first perimeter 202, to the thin (inner in this example) edge of the sloped region 150, as defined by the second perimeter 204. It should be noted that for the purpose of the present invention, the horizontal distance 206 may be, but is not required to be, constant along a perimeter such as the first perimeter 202. The horizontal distance may vary along the first perimeter 202 and/or vary inside a manufacturing process.

The horizontal area (e.g., the entire area) of the transmissive part 101, as seen in the top plan view of FIG. 2B, may be configured based on a target (or desired) light transmission and/or a transmission efficiency per unit area of the transmissive part 101. To determine (the size of) the areas of the transmissive part 101, the transmission efficiency of the transmissive part 101 per unit area may be determined under a controlled lighting condition. For example, under a particular light source, a maximum amount of light transmitted through the subpixel 100 as viewed by a viewer may be measured or calculated. Similarly, a minimum amount of light—light leakage, for example—transmitted through the subpixel 100 may also be measured or calculated. Additionally and/or optionally, other types of transmission efficiency for the subpixel 100 may also be taken or derived from measurement. In various embodiments, other types of transmission efficiencies for a subpixel, such as average, median, ¾ of maximum, etc., may also be taken or derived from measurement.

In some embodiments in which a RGB color system is used, the area size of the subpixel 100 may be set differently depending on whether the subpixel is used as a red subpixel, a green subpixel, or a blue subpixel.

In some embodiments, the horizontal shape (as projected to the display panel surface) of the perimeter of the transition region may be selected among a plurality of possible alternative shapes based on one or more factors or constraints. The one or more constraints may comprise at least a manufacturing process constraint. The one or more constraints may comprise at least a geometric constraint. The one or more constraints may comprise at least a design-tool constraint.

Under techniques as described herein, one or more constraints may be determined and used in selecting one of the many possible alternatives that provides a maximal area of the transmissive part of a subpixel (different color subpixels may each be sized differently). Zero or more of the constraints may be derived from the properties and/or limitations of spatial, physical, and/or optical structures of the subpixel or the transflective display panel. Zero or more of the constraints may be derived from the properties and/or limitations of a design tool (e.g., a CAD tool) used to design the subpixel or the transflective display panel. Zero or more of the constraints may be derived from the properties and/or limitations of a target manufacturing process used to manufacture the subpixel or the transflective display panel. Zero or more of the constraints may be derived from the properties and/or limitations of materials used to produce the subpixel or the transflective display panel. In some embodiments, zero or more of the constraints may be derived based on dimensions of the LCD, dimensions of pixels, power consumption consideration, readability consideration, designated lighting conditions, etc. For the purpose of the present invention, the phrase “maximal area of the transmissive part” may refer to a chosen transmissive area (e.g., 15%, 40%, or another desired percentile of the total subpixel area as projected to a viewing surface of a display panel comprising the subpixel) for which the perimeter is minimized In some embodiments, the transmissive area constitutes merely a small portion (e.g., 15%) of the total area of the subpixel, as such a small transmissive part already meets the design target. Under techniques as described herein, whatever the transmissive area is chosen (15%, 40%, the maximum available area, etc), a rounded perimeter may be used to minimize or reduce the size (e.g., horizontal area) of the transition region.

In embodiments, for the purpose of determining relative sizes of the horizontal areas of the transmissive parts, a different color system may be chosen instead of the RGB system as described above; similar analysis applies with the different color system. Furthermore, a color system under the techniques as described herein needs not be a tri-color system, but may include four or more subpixels of four colors, five colors, etc. in a pixel.

In some embodiments, a constraint may exist to limit the transmissive part 101 to be surrounded within the reflective part 102 or in the interior of the subpixel 100. For a given horizontal area of the transmissive part 101, the smallest perimeter is achieved by enclosing the transmissive part 101 with a circle. This pixel design for a transflective LCD is selected from many possible shapes (square, rectangle, triangle, hexagon, irregular shape, etc.) based on the constraint, and provides a maximal horizontal area of the transmissive part 101 and a minimal perimeter of the transition region 103.

In some embodiments, a constraint may exist to limit the transmissive part 101 to comprise a straight line segment in its overall perimeter along the upper edge of the subpixel 100. Techniques as described herein may be used to select a semicircle for the horizontal area of the transmissive part 101 as illustrated in FIG. 2C.

In some embodiments, one or more constraints may exist to limit/confine the transmissive part 101 within the boundary of a rectangle in the interior of the subpixel 100. Instead of the circle shape of FIG. 2A, the perimeter of the transmissive part 101, or the second perimeter 204, may be configured as close to a circle as possible, for example, in the form of an ellipse shape (not shown).

In some embodiments, the constraints may limit/confine the transmissive part 101 within the boundary of a rectangle bordering along the upper edge of the subpixel 100. The perimeter of the transmissive part 101 may be configured/selected to be as close to a portion of circle or ellipse as possible (not shown), to provide a maximal horizontal area of the transmissive part and a minimal (length of) the perimeter 204, and to comply with the constraints. Thus, if it is not possible/desirable to enclose the entire transmissive area with a circle or a semicircle, a minimal perimeter may be provided based on any additional constraints or factors that are in force.

For example, if two edges are to be straight based on some constraints or factors in force, the perimeters of the transition region 103 may be selected to have one of the shapes as shown in FIG. 2B and FIG. 2D.

In some embodiments, it may be possible to place or “hide” at least a portion of the optically suboptimal area of the transition region 103 in the space between subpixels. This area may be already optically inactive in a variety of possible subpixel designs. As shown in FIG. 2C and FIG. 2D, the upper edge of the transmissive part 101 may be located along the top edge of the subpixel 100. There may be manufacturing constraints or factors that require the transmissive area to be more centrally located in the pixel. In that case, the right shape in the figure above may be used, or if there is sufficient available space, a circle may be used.

In some embodiments, CAD-tool-related constraints or other limitations may prevent provisioning of a circle or semi-circle in the pixel layout. In these embodiments, an arcuate segment, a smoothly curved segment, semicircle, or a circle, may be approximated with a series of straight lines, as illustrated in FIG. 2E.

Techniques as described herein may be used to improve manufacturing yield. An etching process may be challenged to produce well-defined sharp corners (e.g., the tangent of a perimeter makes a large discontinuous change). This may be exacerbated by the (desirable) relatively steep slope in the sloped region 150 from the reflective part 102 to the transmissive part 101, as it is not easy to maintain both a steep slope and a well-defined sharply turned corner. Additionally, a rubbing process used to create alignment in liquid crystal material/molecules may not be configured to be able to form appropriate grooves in a sharply squared corner of the perimeter or contour of the transmissive part 101 or the reflective part 102. By rounding a perimeter under techniques as described herein with smooth curves or with slowly turning (with respect to the tangential direction of the perimeter) short line segments lines in the subpixel layout, the actual transmissive part perimeter formed on a substrate may closely match an intended layout with much reduced etching variations. The rubbing performance may also be relatively repeatable than without using the techniques as described herein. All of these factors and considerations positively impact yield.

### 4. Computer System

Embodiments may be used in a variety of LCD applications. In an embodiment, an electronic apparatus comprises a processor and an LCD formed as described above in connection with FIG. 1A, FIG. 1B, and FIG. 2A through FIG. 2E. Examples of apparatus include video monitors, televisions, watches, clocks, and signs. Further, embodiments may comprise computing devices such as laptop computers, tablet computers, notebooks, netbooks, handheld computers, personal digital assistants, cell phones, and other computers having an integral LCD that is formed as described herein and coupled to display driver circuitry that the computer can drive to cause a display.

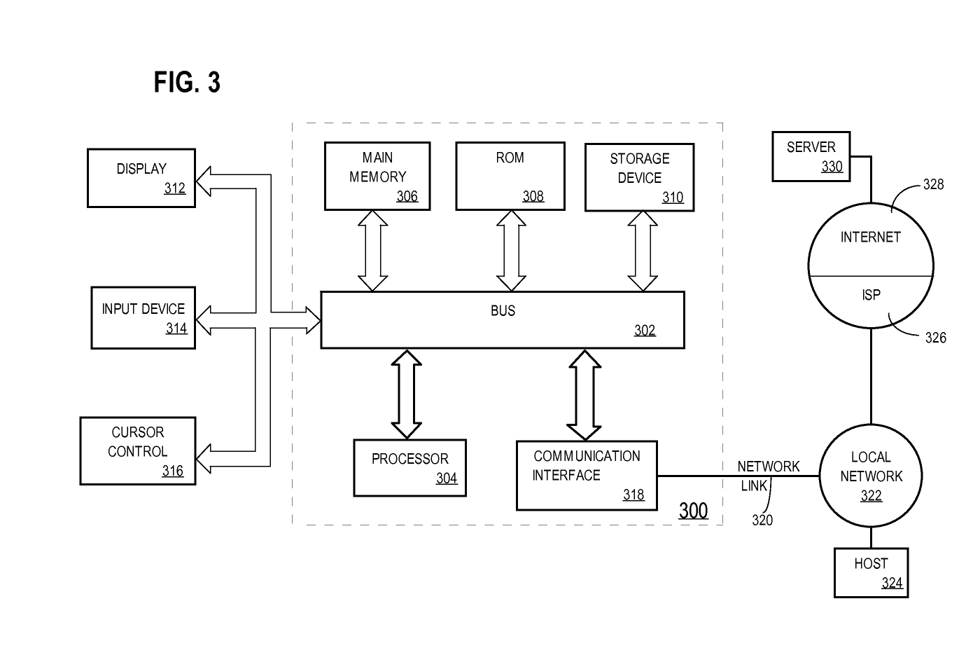

For purposes of illustrating a clear example, FIG. 3 illustrates a computer system 300 with which embodiments may be implemented. In various embodiments, computer system 300 may comprise any of a laptop computer, notebook, netbook, handheld computer, personal digital assistant, cell phone, or another computer having an integral LCD. Special-purpose computing devices such as cell phones comprise additional hardware elements that are omitted in FIG. 3 for clarity, such as an antenna and cellular radiotelephone transceiver.

Computer system 300 includes a bus 302 or other communication mechanism for communicating information, and a hardware processor 304 coupled with bus 302 for processing information. Hardware processor 304 may be, for example, a general purpose microprocessor.

Computer system 300 also includes a main memory 306, such as a random access memory (RAM) or other dynamic storage device, coupled to bus 302 for storing information and instructions to be executed by processor 304. Main memory 306 also may be used for storing temporary variables or other intermediate information during execution of instructions to be executed by processor 304. Computer system 300 further includes a read only memory (ROM) 308 or other static storage device coupled to bus 302 for storing static information and instructions for processor 304. A storage device 310, such as a magnetic disk or optical disk, is provided and coupled to bus 302 for storing information and instructions.

Computer system 300 may be coupled via bus 302 to al display 312, which may be a liquid crystal display in some embodiments. Computer system 300 may comprise a display driver circuit or chipset, separate or integrated with processor 304, configured to drive display 312 with individual LCD pixel display signals based on data that processor 304 writes to the display driver, or obtained directly from a specified part of main memory 306 to which the processor 304 writes data for display. Driver circuit and timing controller may be coupled to processor 304, for example, and to display 312.

An input device 314, including alphanumeric and other keys, is coupled to bus 302 for communicating information and command selections to processor 304. Another type of user input device is cursor control 316, such as a mouse, a trackball, or cursor direction keys for communicating direction information and command selections to processor 304 and for controlling cursor movement on display 312.

Computer system 300 also includes a communication interface 318 coupled to bus 302. Communication interface 318 provides a two-way data communication coupling to a network link 320 that is connected to a local network 322. For example, communication interface 318 may be an integrated services digital network (ISDN) card, cable modem, satellite modem, or a modem to provide a data communication connection to a corresponding type of telephone line. As another example, communication interface 318 may be a local area network (LAN) card to provide a data communication connection to a compatible LAN. Wireless links may also be implemented. In any such implementation, communication interface 318 sends and receives electrical, electromagnetic or optical signals that carry digital data streams representing various types of information.

Network link 320 typically provides data communication through one or more networks to other data devices. For example, network link 320 may provide a connection through local network 322 to a host computer 324 or to data equipment operated by an Internet Service Provider (ISP) 326. ISP 326 in turn provides data communication services through the world wide packet data communication network now commonly referred to as the “Internet” 328. Local network 322 and Internet 328 both use electrical, electromagnetic or optical signals that carry digital data streams. The signals through the various networks and the signals on network link 320 and through communication interface 318, which carry the digital data to and from computer system 300, are example forms of transmission media.

Computer system 300 can send messages and receive data, including program code, through the network(s), network link 320 and communication interface 318. In the Internet example, a server 330 might transmit a requested code for an application program through Internet 328, ISP 326, local network 322 and communication interface 318. The received code may be executed by processor 304 as it is received, and/or stored in storage device 310, or other non-volatile storage for later execution.

### 5. Extensions and Alternatives

Embodiments may be integrated into a transflective LCD of the type described in prior U.S. patent application Ser. No. 12/712,439, filed Feb. 25, 2010. Embodiments may be integrated into a triple mode LCD of the type described in U.S. patent application Ser. No. 12/782,574, filed May 18, 2010.

For the purpose of illustrations only, it has been described that a transmissive part may be confined within a rectangle or between two vertical lines or along an upper border of a subpixel. However, embodiments of the present invention include other forms of geometric constraints. For example, the transmissive part may be confined within other shapes such as triangle, pentagon, hexagon, or another shape other than a rectangle, or other lines (e.g., horizontal lines) other than vertical lines. Additionally, a transmissive part as described herein may be located in the corner of a subpixel, or along a different border or different borders of a subpixel.

For the purpose of illustrations only, it has been described that design-tool or manufacturing-process constraints may be satisfied by using a plurality of line segments to approximate a curved shape that minimizes the horizontal surface of the transition region in a subpixel. However, embodiments of the present invention include other ways of satisfying these constraints. For example, the perimeter of the transmissive part or the reflective part in a subpixel may be approximated or joined together by liner or non-linear segments that are within certain angles. For example, in some embodiments, a more curved part of a perimeter may be approximated by a larger number of shorter segments, while a less curved part of the perimeter may be approximated by a smaller number of longer segments.

In some embodiments, geometric constraints on perimeters of transmissive and reflective parts in a subpixel may be indirectly derived from manufacturing constraints (e.g., associated with an etching sub-process). For example, a manufacturing constraint may limit how much verticality may be accomplished with respect to the over-coating layer in the subpixel. This constraint may be satisfied by designing the perimeter of the transmissive part not to be a rectangle, but rather a gently varying shape that avoids sharp 90-degree changes of directions. In reality, a rectangle shape (or a squared-off shape) for the perimeter of a transmissive, even if so specified by the design, might not be made properly by a manufacturing process. The manufacturing process would likely introduce rounded slopes in the sharply turned corners of the rectangle shape. Indeed, the rounding of the corners by the manufacturing process might be unpredictable and varying. This would reduce the yield and decrease the quality of display panels. Under techniques as described herein, sharp corners may be avoided and replaced with a perimeter that is rounded or curved at the same time when the transition region is minimized Since the perimeter of a transmissive part as described herein avoids sharp corners (e.g., with nearly 90-degree turns), rubbing cloth may be relatively easily applied with the gentle curved shape to create a rubbing direction for the alignment of the liquid crystal material in the subpixel. As a result, the manufacturing of a subpixel as described herein is more tightened, predictable and stable, and produces higher yield and better quality, than without using the techniques herein.

What is claimed is:

1. A transflective liquid crystal display comprising a plurality of subpixels, each subpixel comprising:
a reflective part comprising a reflective part cell gap;
a transmissive part comprising: a transmissive part cell gap;
one or more minimal perimeters of a first minimal area between the transmissive part and the reflective part, wherein at least one of the one or more minimal perimeters defines one or more edges of a second maximal area of the transmissive part.

2. The transflective liquid crystal display according to claim 1, wherein the at least one of the one or more minimal perimeters comprises at least one arcuate segment.

3. The transflective liquid crystal display according to claim 1, wherein the at least one of the one or more minimal perimeters is circular.

4. The transflective liquid crystal display according to claim 1, wherein the at least one of the one or more minimal perimeters is a semicircle.

5. The transflective liquid crystal display according to claim 1, wherein the at least one of the one or more minimal perimeters comprises at least one linear segment and at least one arcuate segment.

6. The transflective liquid crystal display according to claim 1, wherein the at least one of the one or more minimal perimeters comprises a plurality of interconnected linear segments that approximate an arcuate segment.

7. The transflective liquid crystal display according to claim 1, wherein the at least one of the one or more minimal perimeters comprises: a first line segment terminating at a first endpoint on a boundary line segment of the subpixel and a second endpoint; a second line segment terminating at a third endpoint on the boundary line segment of the subpixel and a fourth endpoint; and an arcuate segment joining the first line segment at the second endpoint and the second line segment at the fourth endpoint.

8. A computing device, comprising:
one or more processors;
a transflective liquid crystal display comprising a plurality of subpixels, each subpixel comprising:
a reflective part comprising a reflective part cell gap;
a transmissive part comprising: a transmissive part cell gap;
one or more minimal perimeters of a first minimal area between the transmissive part and the reflective part, wherein at least one of the one or more minimal perimeters defines one or more edges of a second maximal area of the transmissive part.

9. The computer device according to claim 8, wherein the at least one of the one or more minimal perimeters comprises at least one arcuate segment.

10. The computer device according to claim 8, wherein the at least one of the one or more minimal perimeters is circular.

11. The computer device according to claim 8, wherein the at least one of the one or more minimal perimeters is a semicircle.

12. The computer device according to claim 8, wherein the at least one of the one or more minimal perimeters comprises at least one linear segment and at least one arcuate segment.

13. The computer device according to claim 8, wherein the at least one of the one or more minimal perimeters comprises a plurality of interconnected linear segments that approximate an arcuate segment.

14. The computer device according to claim 8, wherein the perimeter of the transmissive part comprises: a first line segment terminating at a first endpoint on a boundary line segment of the subpixel and a second endpoint; a second line segment terminating at a third endpoint on the boundary line segment of the subpixel and a fourth endpoint; and an arcuate segment joining the first line segment at the second endpoint and the second line segment at the fourth endpoint.

15. A method of fabricating a transflective liquid crystal display, comprising:
providing a plurality of subpixels, each subpixel comprising:
a reflective part with a reflective-part cell gap;
a transmissive part with a transmissive-part cell gap;
one or more minimal perimeters of a first minimal area between the transmissive part and the reflective part, wherein at least one of the one or more minimal perimeters defines one or more edges of a second maximal area of the transmissive part.

16. The method according to claim 15, wherein the at least one of the one or more minimal perimeters comprises at least one arcuate segment.

17. The method according to claim 15, wherein the at least one of the one or more minimal perimeters is circular.

18. The method according to claim 15, wherein the at least one of the one or more minimal perimeters is a semicircle.

19. The method according to claim 15, wherein the at least one of the one or more minimal perimeters comprises at least one linear segment and at least one arcuate segment.

20. The method according to claim 15, wherein the at least one of the one or more minimal perimeters comprises a plurality of interconnected linear segments that approximate an arcuate segment.

21. The method according to claim 15, wherein the at least one of the one or more minimal perimeters comprises: a first line segment terminating at a first endpoint on a boundary line segment of the subpixel and a second endpoint; a second line segment terminating at a third endpoint on the boundary line segment of the subpixel and a fourth endpoint; and an arcuate segment joining the first line segment at the second endpoint and the second line segment at the fourth endpoint.
